(19) United States
(12) Patent Application Publication
(10) Pub. No.: US 2013/0147330 A1
(43) Pub. Date: Jun. 13, 2013

(54) METHODS FOR FORMING FIBER-REINFORCED STRUCTURES WITH SEGMENTS FORMED FROM DIFFERENT TYPES OF FIBER

(71) Applicant: Apple Inc., Cupertino, CA (US)

(72) Inventors: John C. DiFONZO, Emerald Hills, CA (US); Amy W. NG, San Francisco, CA (US); Robert Michael MERRITT, Shenzhen (CN)

(73) Assignee: Apple Inc., Cupertino, CA (US)

(21) Appl. No.: 13/711,489

(22) Filed: Dec. 11, 2012

Related U.S. Application Data
(60) Provisional application No. 61/569,714, filed on Dec. 12, 2011.

(30) Foreign Application Priority Data
Sep. 26, 2012 (US) PCT/US12/57394

(51) Int. Cl. H05K 5/03; H05K 13/00

(52) U.S. Cl. CPC H05K 5/03; H05K 13/00
USPC 312/297; 29/527.1

(57) ABSTRACT

Fiber-reinforced structures for use in forming support structures and electronic device housing members may include multiple types of fiber. A first portion of the structures formed from a first type of fiber such as glass fiber may be radio transparent. A second portion of the structures formed from a second type of fiber such as carbon fiber may be more rigid than the first type of fiber and may be radio opaque. The second portion of the structures may be used to selectively add strength to the fiber-reinforced structures. The first portion of the structures may be used to maintain radio transparency for compatibility with wireless electronic device operations. The fiber-reinforced structures may be formed by rolling a sheet of prepreg material that includes a first area with the first type of fiber and a second area with the second type of fiber.

### CROSS REFERENCE TO RELATED APPLICATIONS

This U.S. Patent Application claims priority under 35 U.S.C. 119(e) to U.S. Provisional Patent Application No. 61/569,714, filed Dec. 12, 2011 and entitled “METHODS FOR FORMING FIBER-REINFORCED STRUCTURES WITH SEGMENTS FORMED FROM DIFFERENT TYPES OF FIBER” by DiFonzo et al., which is incorporated by reference in its entirety for all purposes.

### BACKGROUND OF THE INVENTION

This relates to fiber-reinforced materials and, more particularly, to structures formed from fiber-reinforced materials.

Electronic devices sometimes use wireless circuitry. For example, portable electronic devices such as cellular telephones and tablet computers may contain antennas for handling wireless communications. In forming structures such as housings for electronic devices and removable covers for electronic devices, it may be desirable to reduce or eliminate the presence of radio-opaque materials that might interfere with antenna operation.

In some structures, unreinforced plastic is used as a radio-transparent material that is compatible with the presence of antennas. In many applications, however, unreinforced plastic may be undesirably weak.

To address this issue, plastic may be reinforced using fibers. For example, fibers formed from glass and carbon may be used in reinforcing plastic. Carbon fiber reinforced plastic is strong, but is not radio transparent. Glass-fiber reinforced plastic is radio transparent, but may not be sufficiently rigid in certain applications.

It would therefore be desirable to be able to provide fiber-reinforced structures with desired stiffness and radio-frequency transparency attributes.

### SUMMARY

Fiber-reinforced plastic structures may be used in forming support structures and electronic device housing members. The fiber-reinforced plastic structures may include multiple types of fiber. A first portion of the structures may be formed from a first type of fiber such as glass fiber and may be radio transparent. A second portion of the structures may be formed from a second type of fiber such as carbon fiber. The second portion of the structures may be more rigid than the first portion and may be radio opaque.

The second portion of the structures may be used to selectively add stiffness to the fiber-reinforced plastic structures. The first portion of the structures may be used to maintain radio transparency for compatibility with wireless electronic device operations. For example, the first portion may be placed in the vicinity of antennas in a wireless electronic device to allow the antennas to operate without being blocked by the second portion of the structures.

The fiber-reinforced structures may be formed by rolling a sheet of prepreg material to form a roll that is cured in a heated mold. The sheet of prepreg material may include a first area formed using the first type of fiber and a second area formed using the second type of fiber. The shapes of the first and second areas of prepreg material may be configured so that the rolled prepreg material exhibits gradual transitions between the first and second types of fiber and so that the fiber-reinforced plastic structures have strong joints following curing.

Further features of the invention, its nature and various advantages will be more apparent from the accompanying drawings and the following detailed description of the preferred embodiments.

### BRIEF DESCRIPTION OF THE DRAWINGS

FIG. 1 is a perspective view of an illustrative fiber-reinforced plastic structure in accordance with an embodiment of the present invention.

FIG. 2 is a perspective view of an illustrative electronic device and an associated cover in accordance with an embodiment of the present invention.

FIG. 3 is a cross-sectional side view of an illustrative electronic device in a cover showing how a fiber-reinforced structure in the cover may have radio-transparent and non-radio-transparent portions in accordance with an embodiment of the present invention.

FIG. 4 is a cross-sectional view of a portion of a fiber-reinforced structure of the type shown in FIG. 1 in which the fiber-reinforced structure has a triangular cross section in accordance with an embodiment of the present invention.

FIG. 5 is a cross-sectional view of a portion of a fiber-reinforced structure of the type shown in FIG. 1 in which the fiber-reinforced structure has a rectangular cross section in accordance with an embodiment of the present invention.

FIG. 6 is a cross-sectional view of a portion of a fiber-reinforced structure of the type shown in FIG. 1 in which the fiber-reinforced structure has an L-shaped cross section in accordance with an embodiment of the present invention.

FIG. 7 is a diagram showing how a fiber-reinforced plastic structure of the type shown in FIG. 1 may be constructed and incorporated into a finished assembly in accordance with an embodiment of the present invention.

### DETAILED DESCRIPTION

The strength of plastic for use in electronic device housing components, support structures for covers, and other items can be enhanced by incorporating fibers into the plastic. For example, fibers can be incorporated into plastics such as epoxy resins and other polymers to enhance their strength. Examples in which fiber-reinforced plastic structures have been formed from fibers in an epoxy binder are sometimes described herein as an example. In general, any suitable type of plastic may be reinforced with fibers including plastics such as polycarbonate (PC), acrylonitrile butadiene styrene (ABS), PC/ABS blends, epoxy, etc.

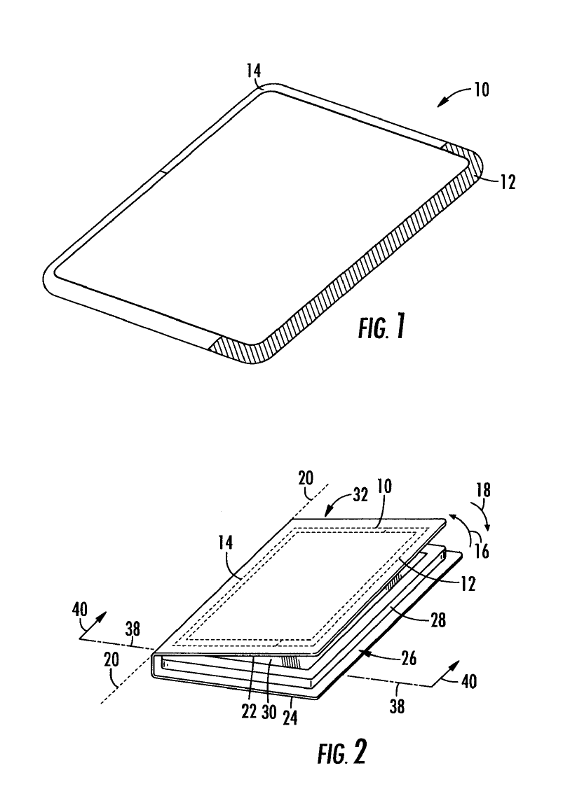

An illustrative fiber-reinforced plastic structure is shown in FIG. 1. In the example of FIG. 1, fiber-reinforced plastic structure 10 has a rectangular ring shape. This is merely illustrative. Fiber-reinforced structure 10 may be formed in a circular ring, a ring having straight and curved sides, may be formed into an L-shaped bar, a straight bar, a curved bar, or may be formed into other suitable shapes.

Fiber-reinforced structure 10 may include multiple portions such as segment 12 and segment 14, each of which may be formed using a different type of fiber. As an example, segment 12 may be formed from a non-radio-transparent (i.e., radio-opaque) material such as a carbon-fiber-reinforced plastic and segment 14 may be formed from a radio-transparent material such as glass—fiber-reinforced plastic. If desired, other fiber-reinforced materials may be used in forming segments 12 and 14 of structure 10. Moreover, more than two different segments may be formed in structure 10. These segments may be located at any suitable locations on structures 10. For example, segment 12 may be located on any of the four sides of a rectangular ring structure, may include any of the four corners of a rectangular ring structure, may extend past one, two, three, or four corners of a rectangular ring structure, may include multiple segments along one side of a rectangular ring structure, may include multiple segments on opposing sides of a rectangular ring structure, may include multiple segments on a circular ring or a ring or strip of material of other shapes, may include segments of the same size or different size in a multi-segment configuration on a rectangular ring, circular ring, straight or curved portion of material, or may include any other pattern of radio-transparent and radio-opaque fiber-reinforced portions. The example of FIG. 1 is merely illustrative.

As shown in FIG. 2, fiber-reinforced structure 10 may be incorporated within a product such as electronic device cover 32. Cover 32 may have an upper flap such as flap 22 and a lower flap such as flap 24. Flaps 22 and 24 may be formed from plastic, leather, or other suitable materials. If desired, cover 32 may have no flaps. For example, cover 32 may be implemented using a slip case design that receives a component such as an electrical device within a slot or other recess within the cover. Cover 32 of FIG. 2 is merely an illustrative example.

Electronic device 26 may be mounted within cover 32. Electronic device 26 may be, for example, a tablet computer or other electronic equipment having a housing such as housing 28 and a display such as display 30. Housing 28 may be formed from metal, glass, ceramic, fiber-reinforced plastic, other materials, or combinations of these materials. If desired, housing 28 may be formed from multiple portions of fiber-reinforced plastic (e.g., one or more segments or other portions of glass-fiber-reinforced plastic, one or more segments or other portions of carbon-fiber-reinforced plastic, etc.). Illustrative arrangements in which fiber-reinforced plastic structure 10 is used in providing support for structures such as cover 32 are sometimes described herein as an example. This is, however, merely illustrative. Fiber-reinforced plastic structure 10 may be incorporated into any suitable apparatus (e.g., electrical equipment, computer accessories, other products, etc.).

Upper flap 22 and lower flap 24 may be joined by a flexible portion of cover 32 along hinge axis 20. When it is desired to open cover 32, a user may lift front flap 22 in direction 16, so that front flap 22 rotates about axis 20 relative to rear flap 24. When it is desired to close cover 32, the user may lower front flap 22 in direction 18.

One or both flaps of cover 32 may be provided with structures such as fiber-reinforced structure 10 of FIG. 1. These fiber-reinforced structures may serve as internal supporting ribs that help hold the potentially flexible plastic or leather material of cover 32 in place. Because segment 12 of structure 10 is formed from carbon-fiber-reinforced plastic (in this example), segment 12 will tend to be stiffer (more rigid) than segment 14 and will therefore help create a stiff, inflexible portion of flap 22, so that flap 22 does not flex excessively when opened and closed by a user.

FIG. 3 is a cross-sectional side view of cover 32 and electronic device 26 taken along line 38 and viewed in direction 40 of FIG. 2 in a configuration in which flap 22 is in its closed position. As shown in FIG. 3, electronic device 26 may contain antenna structures such as antennas 34 that transmit and receive radio-frequency wireless signals 36. Wireless signals 36 may pass through radio-transparent portion 14 of fiber-reinforced structure 10 and the material of cover 32. Because antennas 34 are not located under carbon-fiber-reinforced portion 12 of fiber-reinforced structure 10, antennas 34 and associated radio-frequency antenna signals 36 will not be blocked by conductive materials.

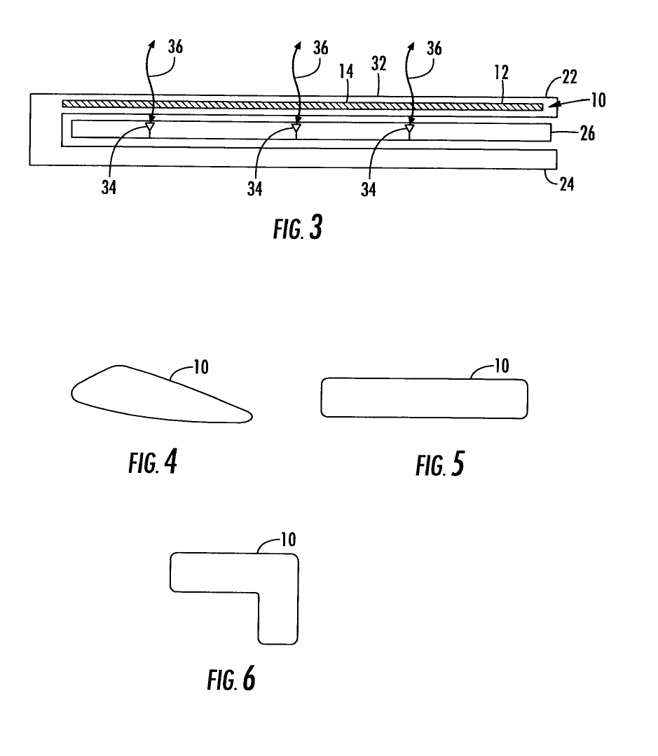

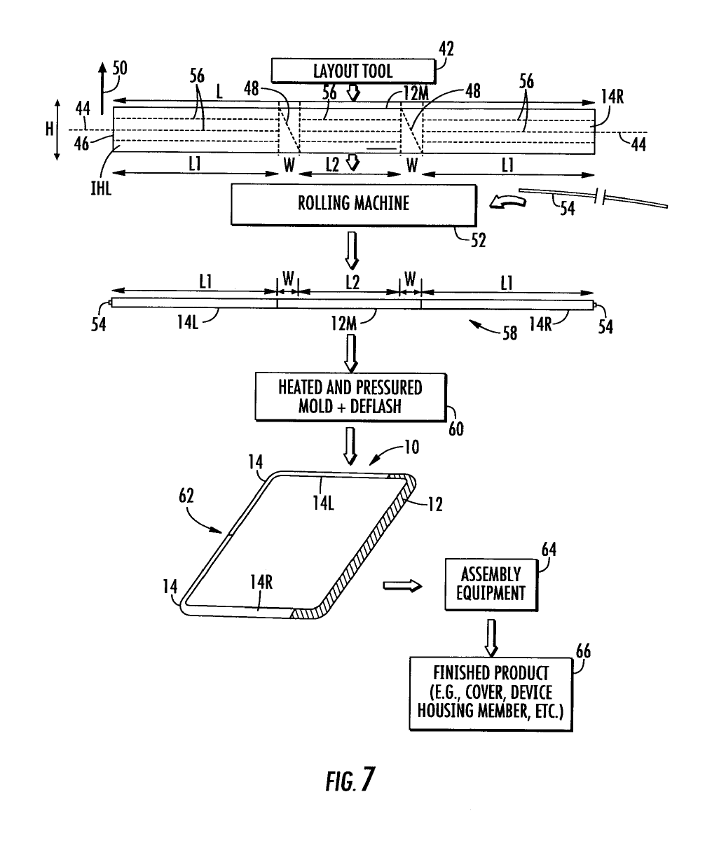

Fiber-reinforced structure 10 may have any suitable cross sectional shape. As an example, fiber-reinforced structure 10 (e.g., segment 12 and/or segment 14) may have a triangular cross-sectional shape as shown in FIG. 4. As another example, fiber-reinforced plastic structure 10 may have a rectangular cross-sectional shape, as shown in FIG. 5. FIG. 6 is a cross-sectional view of fiber-reinforced plastic structure 10 in an illustrative configuration having an L-shaped cross section. Other cross-sectional shapes (e.g., T-shapes, etc.) and segments having combinations of these cross-sectional shapes may be used if desired. Fiber-reinforced plastic structures 10 may be provided with a desired cross-sectional shape using a mold with a corresponding cross-sectional shape, using machining (e.g., to grind rough structures into a desired finished shape), using a combination of molding and machining techniques, or using other suitable fabrication techniques.

FIG. 7 is a diagram showing how fiber-reinforced plastic structures such as structure 10 may be formed and incorporated into an assembly.

Glass fiber and carbon fiber may be incorporated into respective sheets of uncured plastic resin such as epoxy. Sheets of this glass-fiber material and carbon-fiber material (sometimes referred to as prepreg sheets) may be cut into appropriate shapes and arranged on a work surface adjacent to each other using layout tool 42. As shown in FIG. 7, for example, prepreg material 46 may include left glass-fiber prepreg sheet 14L and right glass-fiber prepreg sheet 14R and central carbon-fiber prepreg sheet 12M. There may, in general, be any suitable number of sheets of material with different types of fiber (e.g., one or more, two or more, three or more, four or more, or five or more distinct sheets each with a potentially different type of fiber). The example of FIG. 7 in which there are two sheets of glass-fiber prepreg and a single sheet of carbon-fiber prepreg is merely illustrative.

Prepreg material 46 may have a length L parallel to longitudinal axis (dimension) 44 and a height H parallel to perpendicular lateral dimension 50. Length L may be, as an example, 0.1 to 3 m, less than 3 m, more than 3 m, 0.5 to 1 m, 0.5 to 2 m, less than 0.5 m, more than 0.5 m, more than 1 m, less than 2 m, more than 5 m, less than 5 m, or any other suitable length. Height H may be, as an example, 50-100 mm, less than 10 mm, more than 10 mm, less than 50 mm, more than 50 mm, less than 200 mm, more than 200 mm, less than 300 mm, more than 300 mm, etc. The thickness (into the page in the origination of FIG. 7) of prepreg material 46 may be, for example, 0.05 mm, less than 0.1 mm, more than 0.1 mm, 0.1 mm, between 0.05 and 0.2 mm, less than 0.3 mm, more than 0.1 mm, less than 0.4 mm, more than 0.4 mm, etc. In the illustrative configuration of FIG. 7, prepreg material 46 has an elongated rectangular layout. If desired, prepreg material 46 may have other shapes. The example of FIG. 7 is merely illustrative.

To ensure that the joints between glass-fiber-reinforced segment 14 and carbon-fiber-reinforced segment 12 are satisfactorily strong, it may be desirable to cut edges 48 of sheets 14L, 14M, and 14R at a non-zero angle with respect to lateral dimension 50. If desired, edges 48 may have curved portions, zigzag portions, straight and curved portions, or other configurations that spread out the interface between the different types of prepreg material along longitudinal dimension 44.

As shown in FIG. 7, edges 48 may span the height H of prepreg material 46 in lateral dimension 50 and may cover at least some longitudinal distance W along the length of prepreg material 46. The value of W may be, as an example, 10-80 mm, less than 80 mm, more than 10 mm, etc. The glass fibers in portions 14L and 14R and the carbon fibers in portion 12M may be oriented parallel to longitudinal axis 44, as indicated by fibers 56 in FIG. 7. The illustrative orientation of fibers 56 of FIG. 7 in which fibers 56 run predominantly along the length of the layout may help enhance product strength. If desired, however, woven prepreg or prepreg with fibers that are oriented in different directions can be used. As an example, woven prepreg may be used in situations in which strength and/or stiffness through the cross-section is needed or in situations in which it is desirable to hold the prepreg together during manufacturing. Multiple layers of prepreg with different characteristics may also be used (i.e., some layers may be provided with longitudinally oriented fibers, some layers may have woven fibers, etc.).

After laying out prepreg material 46 (e.g., a single layer or multiple layers) using tool 42, fabrication equipment such as rolling tool 52 may be used to roll prepreg material 46 (e.g., a single layer or multiple layers) onto itself around longitudinal axis 46 to form a roll of prepreg (i.e., an elongated rod or strand of prepreg) such as prepreg roll 58. If desired, an optional fiber such as fiber 54 may be incorporated into the center of prepreg material 46 during the rolling process. Fiber 54 may be formed from a material such as glass or other dielectric or may be formed from other suitable material. The diameter of fiber 54 may be about 1 mm, less than 2 mm, more than 1 mm, between 0.5 and 2 mm, or other suitable size. The presence of fiber 54 may help reduce the amount of carbon fiber that is incorporated into the roll (potentially saving cost) and may facilitate handling of the roll.

In its rolled state, the glass-fiber and carbon-fiber prepreg of roll 58 may be characterized by a length L1 for the exposed portion of left-hand glass-fiber portion 14L, length W+L2 for the exposed (outermost) portion of carbon-fiber portion 12M, and length W+L1 for the exposed portion of right-hand glass-fiber portion 14R. Due to the presence of the non-zero angle of edges 48, there is a gradual transition between glass fibers and carbon fibers throughout the cross-section of roll 58 along widths W.

In region L1 of portion 14L, for example, only glass fibers will be present. In region L2 of portion 12M, only carbon fibers will be present. In transition region W between region L1 of portion 14L and region L2 of portion 12M, however, there will be a smooth changeover as a function of distance along the length of roll 58 between the fully glass fiber section of roll 58 and the fully carbon fiber section of roll 58. The transition between portion 12M and portion 14R of roll 58 will likewise exhibit a smooth transition between carbon fiber and glass fiber. Because there are smooth transitions in the respective concentrations of carbon fiber and glass fiber at the joints between the carbon fiber and glass fiber segments of roll 58, the resulting strength of these joints in the finished (cured) fiber-reinforced plastic parts that are formed will be enhanced. The smooth transition will also generally be visibly smoother and may exhibit reduced warpage, which may improve aesthetics.

To cure uncured prepreg roll 58, uncured prepreg roll 58 may be inserted into a groove or other shape in mold tool 60. Mold tool 60 may include a heated and pressurized mold having two or more portions. As an example, the mold may have a lower metal plate with a groove that has a rectangular ring layout and a V-shaped cross section and may have an upper metal plate that is flat. If desired, other types of cross-sectional shapes may be used (e.g., U-shaped, semi-circular, rectangular, etc.). The ends of sections 14L and 14M of roll 58 may abut one another within mold 60, so that a completed ring shape will be formed after molding.

After inserting uncured prepreg roll 58 into the mold, the mold may apply pressure and an elevated temperature to cure the epoxy (or other plastic). As an example, heated and pressurized mold equipment 60 may apply heat to elevate the temperature of mold 60 and the prepreg material to 120-200° C. for 3-90 minutes, 0.1 to 200 minutes, less than 1 minute, more than 1 minute, less than 4 minutes, more than 4 minutes, 1-50 minutes, 5-20 minutes, less than 20 minutes, more than 20 minutes, 30-45 minutes, less than 45 minutes, or more than 45 minutes (as examples). The heat and pressure of mold 60 will cure the prepreg roll to produce a cured fiber-reinforced plastic part. Stray pieces of plastic may be removed following curing using a deflash process (e.g., using a scraper, blade, or other equipment), thereby producing finished fiber-reinforced plastic structure 10 of FIG. 7.

As shown in FIG. 7, fiber-reinforced plastic structure 10 may have a radio-transparent section such as glass-fiber-reinforced segment 14 and may have a rigid radio-opaque section such as carbon-fiber-reinforced segment 12 (i.e., segment 12 may be less radio-transparent than segment 14). Segment 14 may be formed from portions 14L and 14R of roll 58 and may have a joint (where the ends of portions 14L and 14R abutted one another in the mold) such as joint 62.

Assembly equipment 64 may be used to incorporate fiber-reinforced plastic structure 10 into finished product 66. Product 66 may be an accessory such as a flexible cover for an electronic device (e.g., a tablet computer), may be a housing wall or internal housing structure in a tablet computer, computer, portable telephone or other handheld device, portable computer, music player, television, or other electronic equipment, or may be associated with any other suitable assembly or equipment.

The foregoing is merely illustrative of the principles of this invention and various modifications can be made by those skilled in the art without departing from the scope and spirit of the invention.

What is claimed is:

1. A wireless device cover, comprising:
a front flap including a support frame;
a rear cover; and
a flexible portion coupled to an edge of the front flap and an edge of the rear cover, wherein the flexible portion forms a hinge allowing the front flap to rotate relative to the rear cover;
the support frame further comprising:
a first region comprising a plastic material reinforced by a first set of fibers,
a second region comprising a plastic material reinforced by a second set of fibers, the second set of fibers further comprising a radio-transparent material, wherein the second region is configured to align with an antenna included in a wireless device intended to be placed within the wireless device cover, and
a third region disposed between the first and second regions, in which the first set of fibers gradually transitions to the second set of fibers.

2. The wireless device cover as recited in claim 1, wherein the support frame is formed in the shape of a ring, disposed along a periphery of the front flap.

3. The wireless device cover as recited in claim 2, wherein the ring further comprises a rectangle with rounded corners.

4. The wireless device as recited in claim 2, wherein the first and second sets of fibers are oriented in the direction of the ring.

5. The wireless device as recited in claim 2, wherein the first and second sets of fibers are oriented in a multi-directional weave.

6. The wireless device cover as recited in claim 1, wherein the first set of fibers are comprised of carbon fiber.

7. The wireless device cover as recited in claim 6, wherein the second set of fibers are comprised of glass fibers.

8. The wireless device as recited in claim 7, wherein the plastic material is comprised of an epoxy resin.

9. The wireless device as recited in claim 2, wherein the ring has a rectangular cross-section.

10. The wireless device as recited in claim 2, wherein the ring has an L-shaped cross-section.

11. The wireless device as recited in claim 2, wherein the ring has a triangular cross-section.

12. The wireless device as recited in claim 1, wherein the rear cover includes a second support frame, the second support frame further comprising:
a first region comprising a plastic material reinforced by a first set of fibers,
a second region comprising a plastic material reinforced by a second set of fibers, the second set of fibers further comprising a radio-transparent material, wherein the second region is configured to align with an antenna included in a wireless device intended to be placed within the wireless device cover, and
a third region disposed between the first and second regions, in which the first set of fibers gradually transitions to the second set of fibers.

13. A method for forming a support frame for a wireless device cover, the method comprising:
receiving a first set of fibers and positioning the first set of fibers in a first region of a layout tool;
receiving a second set of fibers formed from a radio-transparent material and positioning the second set of fibers in a second region of a layout tool, wherein a portion of the second set of fibers is allowed to overlap with the first set of fibers to create a third region in which the first set of fibers gradually transitions to the second set of fibers;
creating a prepreg layer by impregnating the first and second sets of fibers with a resin and curing agent;
placing at least one prepreg layer within a mold, wherein the mold is configured to shape the at least one prepreg layer into a support frame;
curing the at least one prepreg layer;
trimming any excess material from the resulting support frame; and
coupling the support frame to a flexible front flap of a wireless device cover.

14. The method as recited in claim 13, wherein the second region is configured to align with an antenna in a wireless device intended to be positioned within the wireless device cover.

15. The method as recited in claim 14, further comprising placing the at least one prepreg layer under pressure during the curing process.

16. The method as recited in claim 15, wherein curing the at least one prepreg layer further comprises applying heat to the prepreg layers for a pre-determined amount of time.

17. The method as recited in claim 15, wherein curing the at least one prepreg layer further comprises exposing the at least one prepreg layer to ultraviolet radiation.

18. The method as recited in claim 14, wherein the first set of fibers are comprised of carbon fiber.

19. The method as recited in claim 18, wherein the second set of fibers are comprised of glass fibers.

20. The method as recited in claim 19, wherein the plastic material is comprised of an epoxy resin.
